(19) United States
(12) Patent Application Publication
(10) Pub. No.: US 2019/0162785 A1
(43) Pub. Date: May 30, 2019

(54) APPARATUS AND METHOD FOR MONITORING PERFORMANCE OF POWER LINE FILTER

(71) Applicant: ELECTRONICS AND TELECOMMUNICATIONS RESEARCH INSTITUTE, Daejeon (KR)

(72) Inventors: Uijung KIM, Daejeon (KR); Namwon MOON, Gwangju (KR); Jinha YOO, Daejeon (KR); Seung-Kab RYU, Sejong-si (KR)

(21) Appl. No.: 15/980,927

(22) Filed: May 16, 2018

(30) Foreign Application Priority Data
Nov. 29, 2017 (KR) 10-2017-0161351

(51) Int. Cl. G01R 31/327; H03H 7/01; H02H 9/04; G01R 23/00

(52) U.S. Cl. CPC G01R 31/3275; G01R 23/00; H02H 9/042; H03H 7/0115

(57) ABSTRACT

An apparatus and method for monitoring the performance of a power line filter. The apparatus for monitoring the performance of a power line filter includes a performance degradation monitoring unit for monitoring performance degradation of individual components constituting a power line filter, and then generating performance degradation information, a frequency characteristic measurement unit for measuring frequency characteristics of the power line filter, and a performance monitoring unit for determining at least one of an operating state and performance of the power line filter based on the performance degradation information of the individual components and information on the frequency characteristics of the power line filter.

### CROSS REFERENCE TO RELATED APPLICATION

This application claims the benefit of Korean Patent Application No. 10-2017-0161351, filed Nov. 29, 2017, which is hereby incorporated by reference in its entirety into this application.

### BACKGROUND OF THE INVENTION

### 1. Technical Field

The present invention relates generally to technology for monitoring the performance of a power line filter, and more particularly, to technology for monitoring the occurrence of a fault and the degradation of performance in a power line filter in an online state in which power is supplied.

### 2. Description of Related Art

A power line filter is a device used to block or suppress a high-power surge and an external noise signal that flow into a system through a power line. The power line filter is installed in the input stage of a power line to prevent external signals from flowing into electronic equipment or facilities.

Such a power line filter may generally include the configuration of a low-pass filter circuit so as to block signals other than that having a power frequency, and may include a Surge Protection Device (SPD) so as to suppress a high-power surge. As representative examples of an SPD, there are a Metal Oxide Varistor (MOV) and a Gas Discharge Tube (GDT). Generally, an MOV characterized by a high response speed and a low residual voltage is chiefly used for power line filters.

Unlike a power line filter for electronic equipment, a power line filter for facilities includes a separate body, is installed in a power input stage so as to prevent external noise signals from flowing into the facilities, and is capable of supplying power to electronic equipment in the facilities. In the case of facilities that use high power, a plurality of power line filters may be installed and operated in each of the facilities.

Electromagnetic compatibility (EMC)/electromagnetic pulses (EMP) power line filters are used for the supply of power to the inside of electromagnetically shielded facilities in which external electromagnetic waves are blocked. A Surge Protection Device (SPD) for protecting circuits from a high-power surge as well as noise transferred through a power line may be installed together with the power line filters.

Meanwhile, performance tests for power line filters include a test for measuring insertion loss to check the blocking of frequencies other than frequencies in a use frequency band, and a Pulse Current Injection (PCI) test for checking the performance of blocking or suppression of external surge signals.

Components constituting a power line filter are gradually degraded as the use periods thereof elapse, and the performance of the power line filter is deteriorated progressively with the degradation of the components. Continuance of the degradation of components may cause faults in the power line filter, and may increase the possibility of the occurrence of incidences, such as the interruption of power supply attributable to the short circuit of a power line, the explosion of degraded components, and the occurrence of a fire.

Further, due to the structural characteristics of a power line filter, even if the performance of blocking or suppression of external surge or noise signals is not normal, the supply of power may be continuously performed, and thus it is difficult to detect the operating state of the power line filter using only the state of power supply.

According to the conventional technology, the performance of a power line can be checked only when a power line filter that is not installed and placed alone. Accordingly, in order to check the performance of the power line filter, a test is performed after the power line is removed from the power line filter. That is, in order to measure the performance of the power line, the supply of power must be interrupted and the power line filter must be conveyed to test equipment, thus making it difficult to periodically examine the state of the power line filter.

Furthermore, conventional degradation diagnosis technologies for power line filters are configured merely to indicate the states of degradation of individual components or to indicate whether an external surge has been input and the number of times the external surge is input, thus making it difficult to provide accurate information on the performance of power line filters.

Therefore, there is required the development of technology that diagnoses the performance of power line filters based on components constituting the power line filter and integrated performance data, and the development of a central management system that is capable of remotely monitoring a plurality of power line filters. In connection with this, Korean Patent No. 10-1443676 (Date of publication: Sep. 26, 2014) discloses a technology related to “The Intelligent EMP Hardening Shelter System Which Has a Full Automatic Shelter Performance Monitoring.”

### SUMMARY OF THE INVENTION

Accordingly, the present invention has been made keeping in mind the above problems occurring in the prior art, and an object of the present invention is to remotely monitor the occurrence of a fault and the degradation of performance in a power line filter in operation.

Another object of the present invention is to check the characteristics of blocking the flow of a high-power surge into a power line filter and the frequency cutoff characteristics of the power line filter during the operation of the power line filter.

A further object of the present invention is to check operating performance and to secure and provide the basis of maintenance and repair planning without stopping the operation of a power line filter.

Yet another object of the present invention is to check the states of degradation of individual components constituting a power line filter and the integrated operating performance of the power line filter.

Still another object of the present invention is to efficiently maintain a plurality of power line filters in an environment in which the power line filters are simultaneously monitored.

In accordance with an aspect of the present invention to accomplish the above objects, there is provided an apparatus for monitoring performance of a power line filter, including a performance degradation monitoring unit for monitoring performance degradation of individual components constituting a power line filter, and then generating performance degradation information; a frequency characteristic measurement unit for measuring frequency characteristics of the power line filter; and a performance monitoring unit for determining at least one of an operating state and performance of the power line filter based on the performance degradation information of the individual components and information on the frequency characteristics of the power line filter.

The performance degradation monitoring unit may generate the performance degradation information including at least one of leakage current information of the individual components, charging current information of the individual components, temperature information, and vibration information.

The performance degradation monitoring unit may monitor performance degradation of the components that include at least one of a surge-protection device and a capacitor of the power line filter.

The apparatus may further include a communication unit for transmitting at least one of the performance degradation information and the frequency characteristic information that are monitored at a preset period to an external manager terminal.

The frequency characteristic measurement unit may measure the frequency characteristics of the power line filter in a power-connected state, using online measurement ports connected to an input stage and an output stage of the power line filter.

The frequency characteristic measurement unit may measure the frequency characteristics of the power line filter using a vector network analyzer.

The performance monitoring unit may determine the operating state and the performance of the power line filter using criteria information that includes at least one of performance degradation criteria information for the individual components and frequency characteristic criteria information.

The criteria information may be set based on at least one of state information when the power line filter is initially installed and state information when a configuration of the power line filter is changed.

The performance monitoring unit may reset at least one of a period at which the performance degradation is monitored and the criteria information in accordance with a time elapsed since installation of the power line filter and the components.

The frequency characteristic measurement unit may measure frequency characteristics of the power line filter if it is determined that, as a result of monitoring the performance degradation of the individual components, the performance degradation does not satisfy the performance degradation criteria information for the individual components.

In accordance with another aspect of the present invention to accomplish the above objects, there is provided a method for monitoring performance of a power line filter, the method being performed by an apparatus for monitoring performance of a power line filter, the method including monitoring performance degradation of individual components constituting a power line filter, and then generating performance degradation information; measuring frequency characteristics of the power line filter; and determining at least one of an operating state and performance of the power line filter based on the performance degradation information of the individual components and information on the frequency characteristics of the power line filter.

Monitoring the performance degradation of the individual components may be configured to generate the performance degradation information including at least one of leakage current information of the individual components, charging current information of the individual components, temperature information, and vibration information.

Monitoring the performance degradation of the individual components may be configured to monitor performance degradation of the components that comprises at least one of a surge-protection device and a capacitor of the power line filter.

The method may further include transmitting at least one of the monitored performance degradation information and the frequency characteristic information that are monitored at a preset period to an external manager terminal.

Measuring the frequency characteristics may be configured to measure the frequency characteristics of the power line filter in a power-connected state using online measurement ports connected to an input stage and an output stage of the power line filter.

Measuring the frequency characteristics may be configured to measure the frequency characteristics of the power line filter using a vector network analyzer.

Determining the at least one of the operating state and the performance of the power line filter may be configured to determine the operating state and the performance of the power line filter using criteria information that includes at least one of performance degradation criteria information for the individual components and frequency characteristic criteria information.

The criteria information may be set based on at least one of state information when the power line filter is initially installed and state information when a configuration of the power line filter is changed.

The method may further include resetting at least one of a period at which the performance degradation is monitored and the criteria information in accordance with a time elapsed since installation of the power line filter and the components.

Measuring the frequency characteristics may be configured to measure frequency characteristics of the power line filter if it is determined that, as a result of monitoring the performance degradation of the individual components, the performance degradation does not satisfy the performance degradation criteria information for the individual components.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram schematically illustrating an environment to which an apparatus for monitoring the performance of a power line filter is applied according to an embodiment of the present invention;

FIG. 2 is a block diagram illustrating the configuration of an apparatus for monitoring the performance of a power line filter according to an embodiment of the present invention;

FIG. 3 is a flowchart for explaining a method for monitoring the performance of a power line filter according to an embodiment of the present invention;

FIG. 4 is a flowchart for explaining a method for monitoring the degradation of performance of individual components according to an embodiment of the present invention;

FIG. 5 is a flowchart for explaining a method for measuring the frequency characteristics of a power line filter according to an embodiment of the present invention;

FIG. 6 is a flowchart for explaining a method for monitoring the performance of a power line filter according to another embodiment of the present invention;

FIG. 7 is a flowchart for explaining a method for monitoring the performance of a power line filter and outputting a warning message according to a further embodiment of the present invention;

FIG. 8 is a diagram illustrating the configuration of a power line filter according to an embodiment of the present invention;

FIG. 9 is a diagram illustrating the configuration of an apparatus for monitoring the performance of a power line filter according to an embodiment of the present invention;

FIG. 10 is a diagram for explaining the measurement of performance degradation information by the apparatus for monitoring the performance of a power line filter according to an embodiment of the present invention; and

FIG. 11 is a block diagram illustrating a computer system according to an embodiment of the present invention.

### DESCRIPTION OF THE PREFERRED EMBODIMENTS

The present invention may be variously changed and may have various embodiments, and specific embodiments will be described in detail below with reference to the attached drawings.

However, it should be understood that those embodiments are not intended to limit the present invention to specific disclosure forms and they include all changes, equivalents or modifications included in the spirit and scope of the present invention.

The terms used in the present specification are merely used to describe specific embodiments and are not intended to limit the present invention. A singular expression includes a plural expression unless a description to the contrary is specifically pointed out in context. In the present specification, it should be understood that the terms such as “include” or “have” are merely intended to indicate that features, numbers, steps, operations, components, parts, or combinations thereof are present, and are not intended to exclude a possibility that one or more other features, numbers, steps, operations, components, parts, or combinations thereof will be present or added.

Unless differently defined, all terms used here including technical or scientific terms have the same meanings as the terms generally understood by those skilled in the art to which the present invention pertains. The terms identical to those defined in generally used dictionaries should be interpreted as having meanings identical to contextual meanings of the related art, and are not interpreted as being ideal or excessively formal meanings unless they are definitely defined in the present specification.

Embodiments of the present invention will be described in detail with reference to the accompanying drawings. In the following description of the present invention, the same reference numerals are used to designate the same or similar elements throughout the drawings and repeated descriptions of the same components will be omitted.

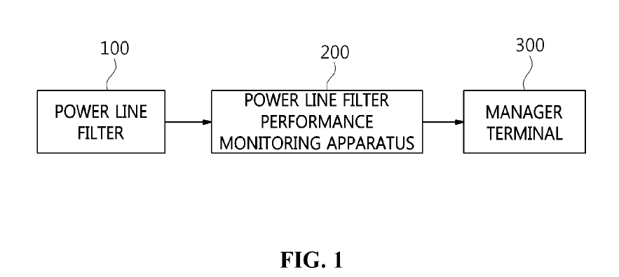

FIG. 1 is a diagram schematically illustrating an environment to which an apparatus for monitoring the performance of a power line filter is applied according to an embodiment of the present invention.

As illustrated in FIG. 1, a system for monitoring the performance of a power line filter may include one or more power line filters 100, an apparatus 200 for monitoring the performance of a power line filter (hereinafter also referred to as a “power line filter performance monitoring apparatus 200”), and a manager terminal 300.

First, each power line filter 100 suppresses or blocks a high-power surge and an external noise signal that are transferred through a power line. Generally, the power line filter 100 may be installed in the input stage of a power line in electronic equipment or in electromagnetically shielded facilities to be protected, and may prevent external signals from flowing into the electronic equipment or the electromagnetically shielded facilities.

The power line filter 100 may include a surge suppressor and a low-pass filter, wherein the surge suppressor may include a Surge Protection Device (SPD) and the low-pass filter may include a capacitor.

The power line filter performance monitoring apparatus 200 is configured to monitor the occurrence of a fault and the degradation of performance in the power line filter 100 in an online state (i.e. in a power-connected state), in which the power is supplied thereto, and to allow a manager to determine, based on the monitored results, whether a fault has occurred in the power line filter 100 or whether there is a need to replace the power line filter.

The power line filter performance monitoring apparatus 200 according to an embodiment of the present invention allows the manager to check the states of degradation of individual components constituting the online power line filter 100, which is supplied with power and is in operation, and the performance of the power line filter. By means of this, the power line filter performance monitoring apparatus 200 may determine whether the power line filter 100 is operating normally, and may enable effective maintenance and management of the power line filter 100.

The power line filter performance monitoring apparatus 200 monitors the degradation of performance of the individual components of the power line filter 100 and measures the frequency characteristics of the power line filter 100. Here, the power line filter performance monitoring apparatus 200 may measure currents, temperatures, and vibrations of the SPD and the capacitor, respectively, and may then monitor the performance degradation of the individual components.

Further, the power line filter performance monitoring apparatus 200 may determine the operating state and performance of the power line filter 100 based on information on the performance degradation of the individual components and information on the frequency characteristics of the power line filter.

Here, the power line filter performance monitoring apparatus 200 may output the results of monitoring of the power line filter 100 to the manager via an output device provided therein, or may transmit the monitored results to the external manager terminal 300.

Furthermore, the power line filter performance monitoring apparatus 200 may be connected to a plurality of power line filters 100 and may monitor the operating states and performance of the power line filters 100. Also, the power line filter performance monitoring apparatus 200 may be implemented to transmit the results of monitoring of the plurality of power line filters 100 to the manager terminal 300, thus allowing the manager terminal 300 to always remotely monitor the performance of the power line filters 100.

For convenience of description, in FIG. 1, the power line filter performance monitoring apparatus 200 is illustrated as being connected to one power line filter 100 to monitor the performance degradation of the individual components of the power line filter 100 and to measure the frequency characteristics thereof.

However, the present invention is not limited thereto, and the power line filter performance monitoring apparatus 200 according to the embodiment of the present invention may be applied to an environment in which a plurality of power line filters 100 are simultaneously monitored. Through this configuration, the plurality of power line filters may be efficiently maintained.

In addition, the manager terminal 300 may receive the results of monitoring of one or more power line filters 100 from the power line filter performance monitoring apparatus 200, and may provide the monitored results to the manager.

For convenience of description, although the power line filter performance monitoring apparatus 200 has been described as determining the operating state and performance of each power line filter 100 based on performance degradation information of the individual components and on the frequency characteristic information, the present invention is not limited thereto. In other words, the power line filter performance monitoring apparatus 200 may be configured to transmit the performance degradation information of the individual components and the frequency characteristic information to the manager terminal 300 and to allow the manager terminal 300 to analyze the operating state and performance of the power line filter 100.

The manager terminal 300 may receive the performance degradation information of individual components of each of the plurality of power line filters 100 and the frequency characteristic information of the power line filters 100, or may receive the operating state and performance information (monitored results) of the plurality of power line filters 100, and may always remotely monitor the performance of power line filters 100.

Further, the manager terminal 300 may provide information on the states of degradation of the components of each power line filter 100 to the manager based on the monitored results, and may notify the manager of the time to replace the components, the time at which maintenance is required, etc.

That is, the power line filter performance monitoring apparatus 200 according to the embodiment of the present invention may provide the manager with information on the states of degradation of individual components of each power line filter 100, expected surge-suppression performance of each power line filter 100, and expected performance of the low-pass filter, thus allowing the manager to determine the necessity for maintenance and repair of each power line filter 100.

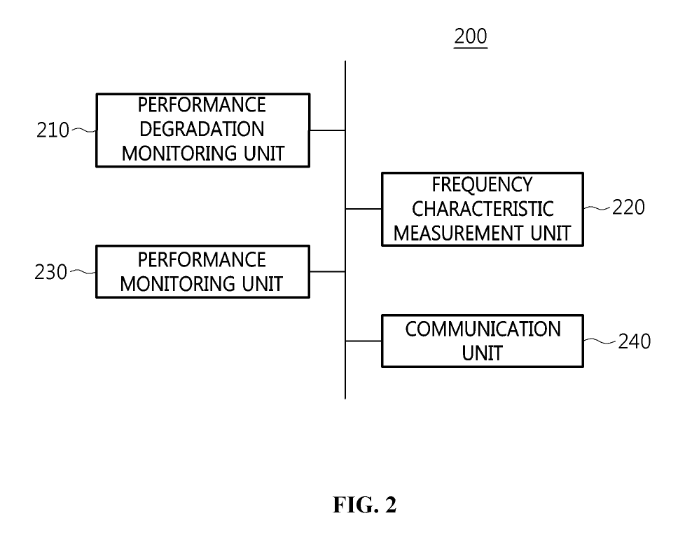

Hereinafter, the configuration of an apparatus for monitoring the performance of a power line filter according to an embodiment of the present invention will be described in detail with reference to FIG. 2.

FIG. 2 is a block diagram illustrating the configuration of an apparatus for monitoring the performance of a power line filter according to an embodiment of the present invention.

As illustrated in FIG. 2, the power line filter performance monitoring apparatus 200 may include a performance degradation monitoring unit 210, a frequency characteristic measurement unit 220, a performance monitoring unit 230, and a communication unit 240.

First, the performance degradation monitoring unit 210 monitors the degradation of performance of individual components constituting a power line filter 100, and then generates performance degradation information. Here, the components of the power line filter 100 may include at least one of an SPD and a capacitor included in the power line filter 100.

Further, the performance degradation monitoring unit 210 may measure and generate performance degradation information including at least one of leakage current information, charging current information, temperature information, and vibration information of the individual components.

Next, the frequency characteristic measurement unit 220 measures the frequency characteristics of the power line filter 100.

The frequency characteristic measurement unit 220 may measure the frequency characteristics of the power line filter 100 in a power-connected state using online measurement ports connected to the input stage and the output stage of the power line filter. Further, the frequency characteristic measurement unit 220 may measure the frequency characteristics of the power line filter using a Vector Network Analyzer (VNA).

Here, the frequency characteristic measurement unit 220 may measure the frequency characteristics when an abnormality is found to be detected in the components of the power line filter 100 as a result of comparison of the performance degradation information, generated by the performance degradation monitoring unit 210, with performance degradation criteria information, or may measure frequency characteristics at a periodic inspection time.

Further, the performance monitoring unit 230 may determine at least one of the operating state and performance of the power line filter 100 based on the performance degradation information of the individual components and the frequency characteristic information of the power line filter 100.

The performance monitoring unit 230 may determine the operating state and performance of the power line filter 100 using criteria information including at least one of performance degradation criteria information of the individual components and frequency characteristic criteria information.

Here, the performance monitoring unit 230 may determine the performance of the power line filter 100 depending on whether a change of a certain level or more occurs by comparing the performance degradation information of the individual components and the frequency characteristic information with the criteria information.

Furthermore, the performance monitoring unit 230 may reset at least one of a period at which performance degradation is monitored and a reference period corresponding to the criteria information depending on the time elapsed since the installation of the power line filter 100 and the components of the power line filter 100. In particular, the performance monitoring unit 230 may monitor the performance degradation of the individual components, and may then reset the period at which the performance degradation of the individual components of the power line filter 100 is monitored such that the monitoring period is shortened.

Finally, the communication unit 240 transmits at least one of the performance degradation information and the frequency characteristic information which are generated as the results of monitoring to the external manager terminal 300. Here, the communication unit 240 may transmit the performance degradation information and the frequency characteristic information to the manager terminal 300 either periodically or whenever performance degradation information and frequency characteristic information are generated.

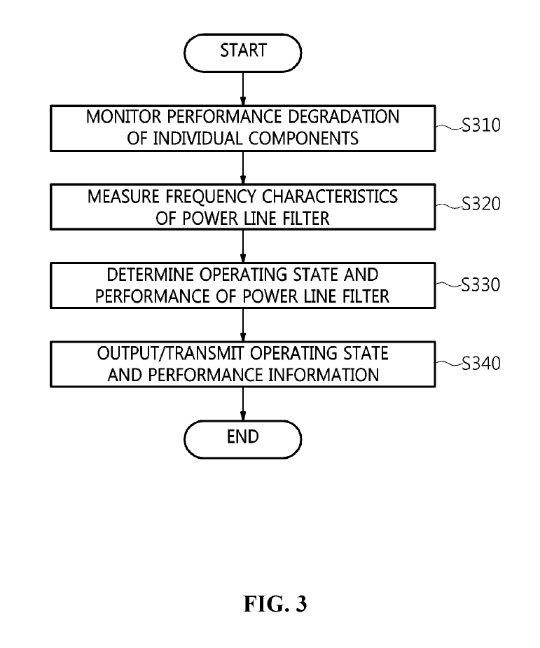

Hereinafter, a method for monitoring the performance of a power line filter performed by the power line filter performance monitoring apparatus according to an embodiment of the present invention will be described in detail with reference to FIG. 3.

FIG. 3 is a flowchart for explaining a method for monitoring the performance of a power line filter according to an embodiment of the present invention.

First, the power line filter performance monitoring apparatus 200 monitors the degradation of performance of individual components at step S310.

The power line filter performance monitoring apparatus 200 may detect the operations of individual components of each power line filter 100, and may monitor the degradation of performance of individual components, such as a Surge Protection Device (SPD) and a capacitor that constitute the power line filter 100.

Here, the power line filter performance monitoring apparatus 200 may measure at least one of currents, temperatures, and vibrations of individual components, such as the SPD and the capacitor. The power line filter performance monitoring apparatus 200 according to the embodiment of the present invention may monitor leakage currents, charging currents, temperatures, and vibrations of the individual components, and may monitor a change in the performance of each component by comparing the monitored results with performance degradation criteria information for the individual components.

Next, the power line filter performance monitoring apparatus 200 measures the frequency characteristics of the power line filter at step S320.

The power line filter performance monitoring apparatus 200 may measure the frequency characteristics of the power line filter in a power-connected state (online state) using online measurement ports connected to the input stage and the output stage of the power line filter. Here, the online measurement ports may collect the results of periodic frequency measurement of the power line filter 100 in operation, and may measure the frequency characteristics of the power line filter in the power-connected state through a vector network analyzer or the like.

The power line filter performance monitoring apparatus 200 may measure insertion loss or the like, which indicates the frequency characteristics of the power line filter 100 in the power-connected state, and may then check whether the power line filter 100 is normally blocking frequencies other than those in a use frequency band.

For convenience of description, the power line filter performance monitoring apparatus 200 has been described as monitoring the degradation of performance of the individual components at step S310 and thereafter performing the step S320 of measuring the frequency characteristics of the power line filter 100, but the present invention is not limited thereto. For example, the design of the present invention may be modified and implemented such that step S320 is performed to measure the frequency characteristics of the power line filter 100 only when the results monitored at step S310 do not satisfy the performance degradation criteria information for the individual components of the power line filter 100, or only when it is determined that a change in the performance of each component is predicted.

Next, the power line filter performance monitoring apparatus 200 analyzes the operating state and performance of the power line filter 100 at step S330.

The power line filter performance monitoring apparatus 200 may analyze the operating state and performance of the power line filter 100 by comparing the performance degradation information of the individual components with the performance degradation criteria information for the individual components, or by comparing the frequency characteristic information of the power line filter 100 with frequency characteristic criteria information.

The power line filter performance monitoring apparatus 200 may determine the degradation of performance of the corresponding components by respectively comparing the leakage current information, charging current information, temperature information, and vibration information, which are pieces of performance degradation information of the individual components, with leakage current criteria information, charging current criteria information, temperature criteria information, and vibration criteria information for the individual components.

Further, the power line filter performance monitoring apparatus 200 may set the results of frequency characteristic information, measured in a power supply state after the power line filter 100 is initially installed, to frequency characteristic criteria information, may compare the results of measurement of frequency characteristic information in the state in which the power line filter 100 is initially installed with the frequency characteristic information of the power line filter 100 measured at step S320, and may then determine whether a change in the performance of the power line filter 100 occurs.

For convenience of description, the power line filter performance monitoring apparatus 200 has been described as comparing the frequency characteristic information measured at step S320 based on the results of frequency characteristic information measured in the state in which the power line filter 100 is initially installed, but the present invention is not limited to this configuration. For example, the power line filter performance monitoring apparatus 200 may compare the frequency characteristic information of the power line filter 100 based on frequency characteristic information that is measured when a principal component in the load stage of the power line filter 100 is changed or on frequency characteristic information that is initially measured by the power line filter performance monitoring apparatus 200.

Finally, the power line filter performance monitoring apparatus 200 may output the results of the analysis or transmit the analysis results to an external device at step S340.

The power line filter performance monitoring apparatus 200 may output the results of analysis of the operating state and the performance at step S330 via an output device provided therein, or may transmit the analysis results to an external device, such as the manager terminal 300.

Here, the power line filter performance monitoring apparatus 200 may output a message, such as “good”, “caution” or “warning” depending on the results of analysis, may output the results of analysis of the individual components, or may output the operating state or performance information of the entire power line filter 100.

Further, the power line filter performance monitoring apparatus 200 may transmit the results of analysis to the external manager terminal 300 so as to implement a central management system for performing remote monitoring.

For convenience of description, the power line filter performance monitoring apparatus 200 has been described as analyzing the operating state and performance of the power line filter 100 and as outputting the analysis results or transmitting the analysis results to the external manager terminal 300, but the present invention is not limited thereto. For example, the present invention may be implemented such that the power line filter performance monitoring apparatus 200 transmits the monitored performance degradation information and frequency characteristic information to the manager terminal 300 and allows the manager terminal 300 to analyze the performance degradation information and the frequency characteristic information to thus analyze the operating state and performance of the power line filter 100.

Here, the procedure in which the manager terminal 300 analyzes the performance degradation information and frequency characteristic information of the power line filter 100 may be substantially identical to the procedure in which the power line filter performance monitoring apparatus 200 determines the operating state and performance at step S330, and thus a repeated description thereof will be omitted.

Also, the power line filter performance monitoring apparatus 200 may perform step S340 immediately after performing step S310, or may perform step S340 immediately after performing step S320, and may periodically perform step S340.

Furthermore, the power line filter performance monitoring apparatus 200 may generate the performance degradation information of the individual components by periodically performing step S310, or may measure frequency characteristic information by periodically performing step S320, and may perform the procedure corresponding to at least one of step S310 and step S320 in response to the settings or request of the manager.

Here, the power line filter performance monitoring apparatus 200 may be operated in accordance with a preset periodic inspection interval, and may reset a periodic inspection interval based on at least one of the results of the operating state and performance determined at step S330, the time elapsed since the installation of the power line filter 100, and the results of previous performance monitoring of the power line filter 100.

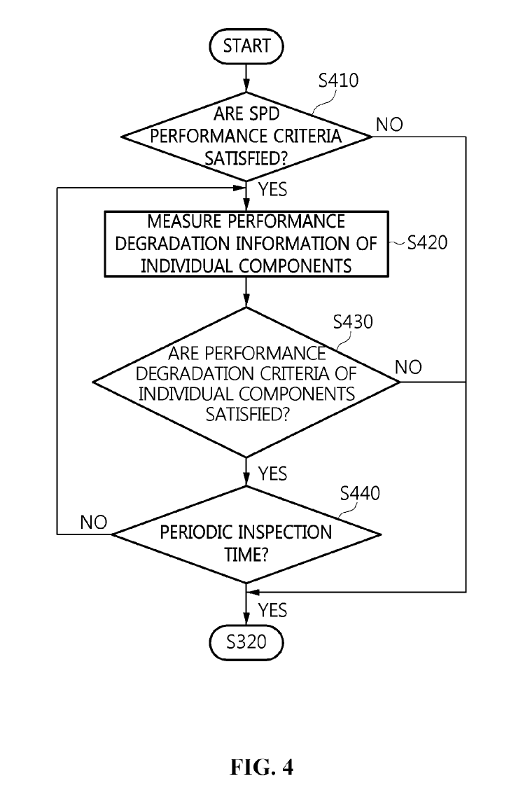

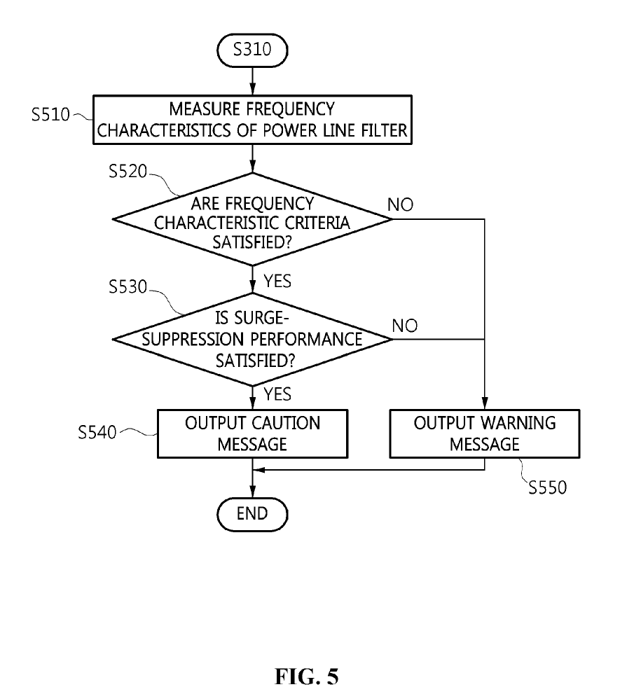

Hereinafter, a method for monitoring the performance degradation of individual components and measuring frequency characteristics by the power line filter performance monitoring apparatus according to other embodiments of the present invention will be described in detail with reference to FIGS. 4 and 5.

FIG. 4 is a flowchart illustrating a method for monitoring the performance degradation of individual components according to an embodiment of the present invention.

First, the power line filter performance monitoring apparatus 200 may determine whether the SPD of the power line filter 100 satisfies SPD performance criteria at step S410.

The power line filter performance monitoring apparatus 200 may check whether the SPD included in the surge suppressor of the power line filter 100 is normally performing high-power surge suppression, and may then determine whether the SPD satisfies the SPD performance criteria.

If it is determined that the SPD satisfies the SPD performance criteria (the case of “Yes” at step S410), the power line filter performance monitoring apparatus 200 measures the performance degradation information of individual components at step S420.

Even if the power line filter 100 does not satisfy the SPD performance criteria and the suppression of an external surge or an external noise signal is not normally performed, the supply of power to the power line filter 100 may be normally continued. Therefore, the operating state of the power line filter 100 may not be effectively determined only using the power supply state of the power line filter 100.

Therefore, even if it is determined that the SPD satisfies the SPD performance criteria, the power line filter performance monitoring apparatus 200 according to the embodiment of the present invention may determine the operating state and performance of the power line filter 100 by additionally measuring the performance degradation information of the individual components of the power line filter 100.

Through this operation, the power line filter performance monitoring apparatus 200 may protect equipment or facilities supplied with power in an abnormal state in which the power line filter 100 continuously supplies power, but cannot block or suppress an external surge or noise signal.

The procedure in which the power line filter performance monitoring apparatus 200 measures the performance degradation information of the individual components at step S420 is substantially identical to step S310 of FIG. 3, and a repeated description thereof will be omitted.

Further, if it is determined that the measured performance degradation information of the individual components satisfies performance degradation criteria for the individual components (the case of “Yes” at S430), the power line filter performance monitoring apparatus 200 determines whether a current time is a periodic inspection time at step S440.

The power line filter performance monitoring apparatus 200 may determine whether the current time is the periodic inspection time corresponding to the periodic inspection interval of the power line filter 100, and may determine whether to perform step S320 of FIG. 3. Here, the periodic inspection interval may be set differently for respective power line filters 100, or may be set differently for respective components of each power line filter 100.

Further, the periodic inspection interval may be set or reset based on the results of determination of the operating state and performance of the power line filter 100, the time elapsed since the initial installation of the power line filter 100, the time elapsed since the replacement of each component, or the like.

For example, when the results of determination of the operating state and performance of the power line filter 100 indicate a “caution” state, the power line filter performance monitoring apparatus 200 may reset the periodic inspection interval to an interval shorter than the previous periodic inspection interval. Further, as time has elapsed since the initial installation of the power line filter 100, or as time has elapsed since the replacement of each component, the power line filter performance monitoring apparatus 200 may reset the periodic inspection interval to a shorter interval.

If it is determined at step S440 that the current time is not a periodic inspection time (the case of “No” at step S440), the power line filter performance monitoring apparatus 200 may return to step S410 or S420, or may terminate the procedure for monitoring the performance of the power line filter 100.

Meanwhile, when the power line filter 100 does not satisfy the SPD performance criteria (the case of “No” at S410), or does not satisfy the performance degradation criteria for the individual components (the case of “No” at step S430), the power line filter performance monitoring apparatus 200 may measure the frequency characteristics of the power line filter 100 by performing step S320 of FIG. 3.

The power line filter performance monitoring apparatus 200 according to the embodiment of the present invention may perform the step of measuring frequency characteristic information (S320 of FIG. 3) only when the power line filter 100 does not satisfy the SPD performance criteria or does not satisfy the performance degradation criteria for the individual components, or only when the current time is the periodic inspection time.

That is, the power line filter performance monitoring apparatus 200 may measure the frequency characteristics of the low-pass filter through the online measurement ports only at the time at which a change in the performance of each component of the power line filter 100 is predicted. Through this measurement, the power line filter performance monitoring apparatus 200 may be efficiently operated.

FIG. 5 is a flowchart for explaining a method for measuring the frequency characteristics of the power line filter according to an embodiment of the present invention.

The power line filter performance monitoring apparatus 200 measures the frequency characteristics of the power line filter 100 at step S510.

The power line filter performance monitoring apparatus 200 may perform step S510 of FIG. 5 after the performance degradation of individual components of the power line filter 100 has been monitored at step S310 of FIG. 3 or if it is determined at step S410 of FIG. 4 that the power line filter 100 does not satisfy the SPD performance criteria, if it is determined at step S430 of FIG. 4 that the power line filter 100 does not satisfy the performance degradation criteria for the individual components, or if it is determined at step S440 of FIG. 4 that the current time is the periodic inspection time.

The procedure in which the power line filter performance monitoring apparatus 200 measures the frequency characteristic information of the power line filter 100 is substantially identical to step S320 of FIG. 3, and thus a repeated description thereof will be omitted.

Next, the power line filter performance monitoring apparatus 200 may determine whether the measured frequency characteristic information satisfies frequency characteristic criteria at step S520.

In detail, the power line filter performance monitoring apparatus 200 determines whether the frequency characteristic information measured at step S510 satisfies preset frequency characteristic criteria or reset frequency characteristic criteria.

If it is determined that the measured frequency characteristic information satisfies the frequency characteristic criteria (the case of “Yes” at step S520), the power line filter performance monitoring apparatus 200 may determine whether the measured frequency characteristic information satisfies surge-suppression performance at step S530.

Further, when the surge-suppression performance is satisfied (the case of “Yes” at step S530), the power line filter performance monitoring apparatus 200 may output a “caution” message at step S540.

Even if the surge-suppression performance of the power line filter 100 is satisfied, the power line filter performance monitoring apparatus 200 may output a “caution” message in the case where it is determined that the information monitored at step S310 of FIG. 3 does not satisfy the performance degradation criteria for the individual components of the power line filter 100 and the procedure of FIG. 5 is then performed.

In this way, the power line filter performance monitoring apparatus 200 may notify the manager of the change in the performance of the power line filter 100 and also notify the manager of the time to perform maintenance by outputting the “caution” message.

In contrast, if it is determined at step S520 that the measured frequency characteristic information does not satisfy the frequency characteristic criteria (the case of “No” at S520), or if it is determined at step S530 that the measured frequency characteristic information does not satisfy the surge-suppression performance (the case of “No” at S530), the power line filter performance monitoring apparatus 200 may output a “warning” message at step S550.

If it is determined that the information monitored step S310 of FIG. 3 does not satisfy the performance degradation criteria for the individual components of the power line filter 100 and the procedure of FIG. 5 is then performed, and if it is determined at step S520 that the measured frequency characteristic information does not satisfy the frequency characteristic criteria or if it is determined at step S530 that the measured frequency characteristic information does not satisfy the surge-suppression performance, the power line filter performance monitoring apparatus 200 may advise the manager to maintain and repair the power line filter 100 by outputting a “warning” message.

Further, the power line filter performance monitoring apparatus 200 may be implemented such that, as illustrated in FIG. 3, the performance degradation information of the individual components of the power line filter 100 is measured, the frequency characteristic information is measured, and thereafter the operating state and performance of the power line filter 100 is determined by comparing the measured information with the criteria information of the power line filter 100, or such that, as illustrated in FIGS. 4 and 5, frequency characteristic information is measured if the performance degradation information of the individual components of the power line filter 100 does not satisfy criteria information. However, the operating form of the power line filter performance monitoring apparatus 200 is not limited thereto.

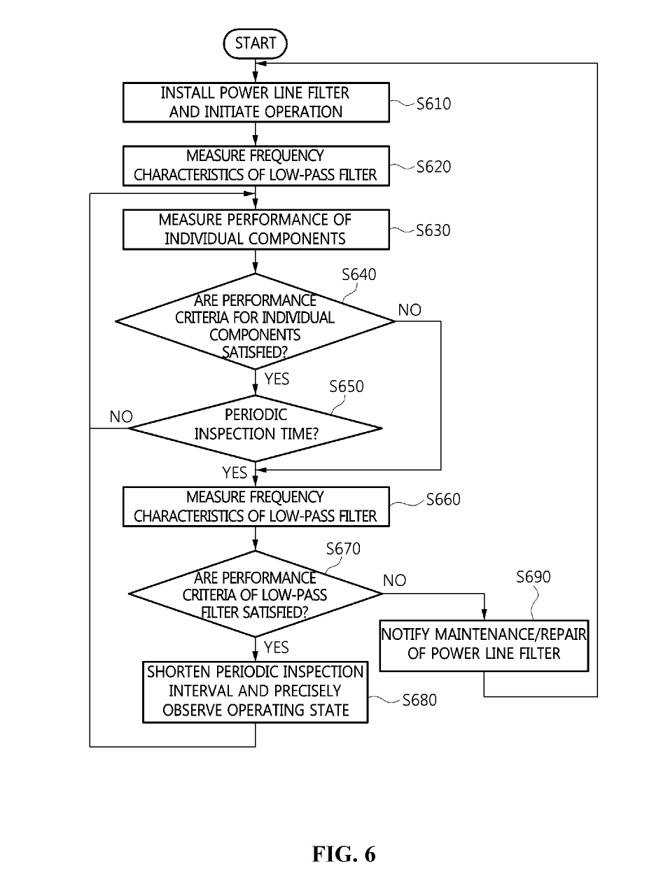

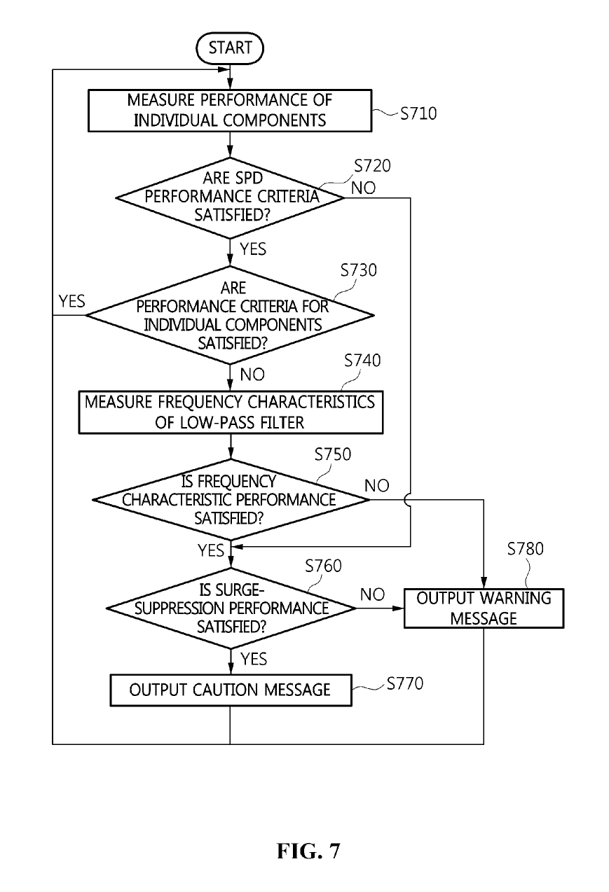

Hereinafter, a method for monitoring the performance of a power line filter and outputting a “warning” message according to other embodiments of the present invention will be described in detail with reference to FIGS. 6 and 7.

FIG. 6 is a flowchart for explaining a method for monitoring the performance of a power line filter according to another embodiment of the present invention.

First, the power line filter performance monitoring apparatus 200 enables one or more power line filters 100 to be installed and initiates the operation thereof at step S610.

Here, the power line filters 100 may be initially installed, or may be re-installed after a maintenance or repair procedure.

The power line filter performance monitoring apparatus 200 measures the frequency characteristics of a low-pass filter at step S620, and measures the performance of individual components of each power line filter at step S630.

The procedure in which the power line filter performance monitoring apparatus 200 measures the frequency characteristics of the low-pass filter provided in each power line filter 100 may be performed by the frequency characteristic measurement unit 220 of FIG. 2, and thus a repeated description thereof will be omitted.

Further, the procedure in which the power line filter performance monitoring apparatus 200 measures the performance of the individual components may be performed by the performance degradation monitoring unit 210 of FIG. 2, and thus a repeated description thereof will be omitted.

Next, the power line filter performance monitoring apparatus 200 determines whether the measured performance of the individual components satisfies the performance criteria for the individual components at step S640, and performs step S660, which will be described later, if it is determined that the measured performance does not satisfy the performance criteria (the case of “No” at step S640).

Conversely, if it is determined that the measured performance satisfies the performance criteria for the individual components (the case of “Yes” at step S640), the power line filter performance monitoring apparatus 200 may determine whether a current time is a periodic inspection time at step S650.

If it is determined that the current time is not a periodic inspection time (the case of “No” at step S650), the power line filter performance monitoring apparatus 200 may return to the step S630 of measuring again the performance of the individual components.

However, if it is determined that the current time is the periodic inspection time (the case of “Yes” at step S650) or if it is determined at step S640 that the measured performance does not satisfy the performance criteria for the individual components (the case of “No” at step S640), the power line filter performance monitoring apparatus 200 may measure the frequency characteristics of the low-pass filter at step S660.

After measuring the frequency characteristics, the power line filter performance monitoring apparatus 200 determines whether the measured frequency characteristics satisfy low-pass filter performance criteria at step S670. If it is determined that the frequency characteristics satisfy the low-pass filter performance criteria (the case of “Yes” at step S670), the periodic inspection interval of the power line filter 100 is shortened, and the operating state of the power line filter 100 is precisely observed at step S680.

Thereafter, the power line filter performance monitoring apparatus 200 may return to step S630 to repeat the procedure for measuring the performance of the individual components and monitoring the performance of the power line filter.

Conversely, if it is determined that the measured frequency characteristics do not satisfy the low-pass filter performance criteria (in the case of “No” at step S670), the power line filter performance monitoring apparatus 200 may request the manager to maintain and repair the power line filter 100 at step S690.

Further, if it is determined that the maintenance/repair of the power line filter 100 has been completed or the replacement of components has been completed, the power line filter performance monitoring apparatus 200 may return to step S610 to continuously monitor the performance of the power line filter 100.

In this way, the power line filter performance monitoring apparatus 200 according to the embodiment of the present invention may always monitor the performance of the power line filter 100.

FIG. 7 is a flowchart for explaining a method for monitoring the performance of a power line filter and outputting a “warning” message according to a further embodiment of the present invention.

As illustrated in FIG. 7, the power line filter performance monitoring apparatus 200 measures the performance of individual components of each power line filter 100 at step S710.

Further, the power line filter performance monitoring apparatus 200 determines whether the measured performance satisfies SPD performance criteria for the power line filter 100 at step S720.

If it is determined that the measured performance does not satisfy the SPD performance criteria (the case of “No” at step S720), the power line filter performance monitoring apparatus 200 may determine whether the measured performance satisfies surge-suppression performance by performing step S760, which will be described later. In contrast, if the measured performance satisfies the SPD performance criteria (the case of “Yes” at step S720), the power line filter performance monitoring apparatus 200 determines whether the measured performance satisfies performance criteria for individual components at step S730.

In this way, the power line filter performance monitoring apparatus 200 may be configured to determine whether the performance of the SPD of the power line filter 100 satisfies SPD performance criteria by performing step S720, and to skip the procedure (steps S730 and S750) for monitoring the performance degradation of the individual components and the frequency characteristics and output a “caution” message or “warning” message if the measured performance does not satisfy the SPD performance criteria.

Conversely, if the measured performance satisfies the SPD performance criteria, the power line filter performance monitoring apparatus 200 may perform the procedure for monitoring the performance degradation of the individual components and frequency characteristics, and thereafter output a “caution” message or a “warning” message based on the results of monitoring the performance degradation of the individual components and the frequency characteristics.

In other words, if it is determined that the measured performance does not satisfy the SPD performance criteria, the power line filter performance monitoring apparatus 200 may perform the step S730 of determining whether the measured performance satisfies performance criteria for the individual components. If the measured performance satisfies the performance criteria for the individual components (the case of “Yes” at step S730), the power line filter performance monitoring apparatus 200 returns to step S710 to repeat the procedure for measuring the performance of the individual components.

Conversely, if it is determined that the measured performance does not satisfy the performance criteria for the individual components (the case of “No” at step S730), the power line filter performance monitoring apparatus 200 measures the frequency characteristics of the low-pass filter at step S740.

Further, the power line filter performance monitoring apparatus 200 may determine whether the frequency characteristics of the low-pass filter satisfy frequency characteristic performance at step S750, and may determine whether the frequency characteristics satisfy surge-suppression performance at step S760 if the frequency characteristics satisfy the frequency characteristic performance (the case of “Yes” at step S750).

If it is determined that the frequency characteristics satisfy the surge-suppression performance (the case of “Yes” at step S760), the power line filter performance monitoring apparatus 200 may output a “caution” message at step S770. If it is determined that the frequency characteristics does not satisfy the surge-suppression performance (the case of “No” at step S760), the power line filter performance monitoring apparatus 200 may output a “warning” message at step S780.

Further, if it is determined at step S750 that the measured frequency characteristics do not satisfy the frequency characteristic performance (the case of “No” at step S750), the power line filter performance monitoring apparatus 200 may perform the step S780 of outputting a “warning” message.

After any one of the “caution” message and the “warning” message has been output, the power line filter performance monitoring apparatus 200 may return to step S710 to repeat the procedure of FIG. 7.

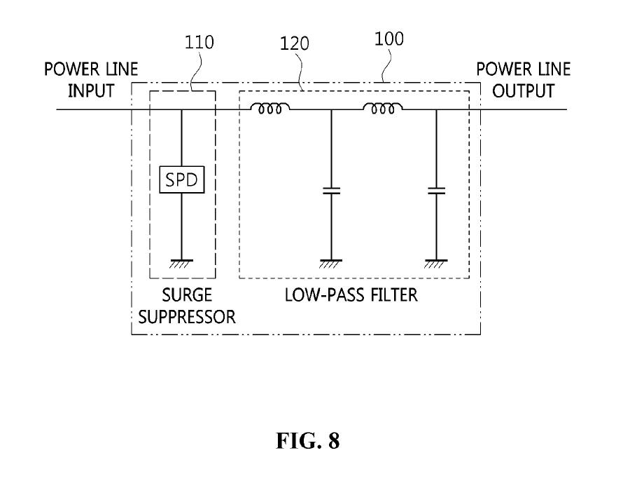

Hereinafter, the configurations of a power line filter and a power line filter performance monitoring apparatus according to an embodiment of the present invention will be described in greater detail with reference to FIGS. 8 to 10.

FIG. 8 is a diagram for explaining the configuration of a power line filter according to an embodiment of the present invention.

As illustrated in FIG. 8, a power line filter 100 may include a surge suppressor 110 and a low-pass filter 120. Further, the surge suppressor 110 may include a Surge Protection Unit (SPD), and the low-pass filter 120 may include a capacitor.

The power line filter 100 includes an input power line and an output power line, and a power line filter performance monitoring apparatus 200 may be installed on each of the input power line and the output power line.

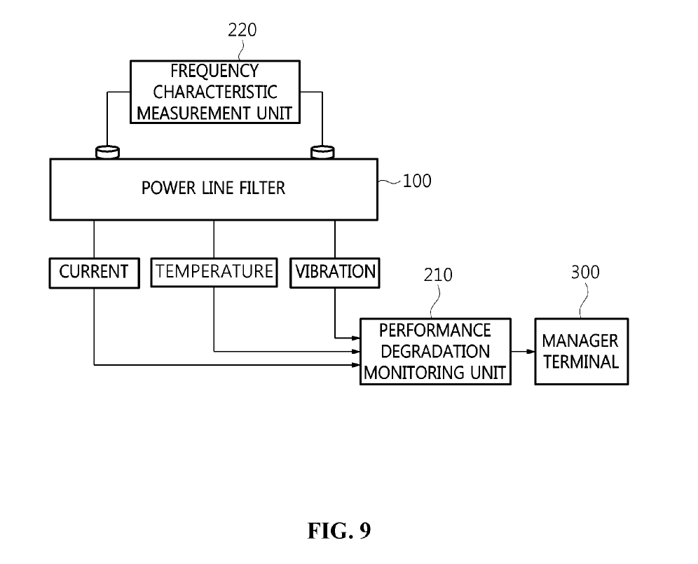

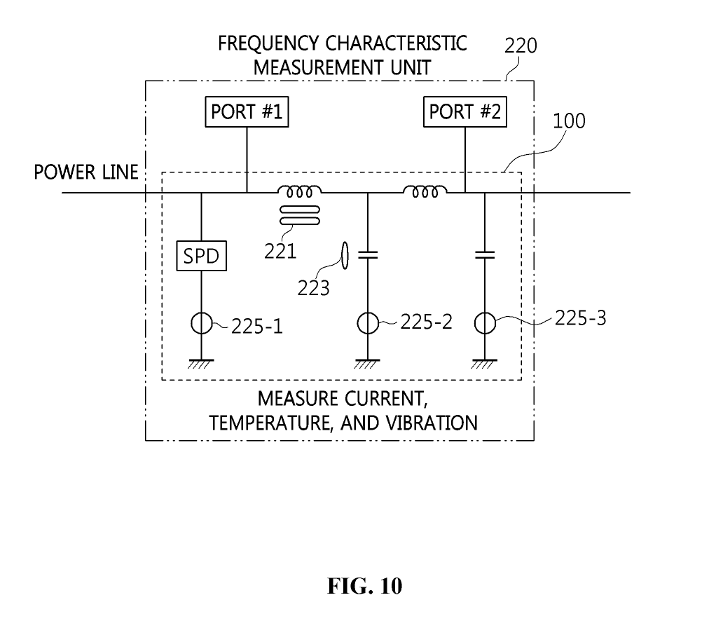

FIG. 9 is a diagram for explaining the configuration of the power line filter performance monitoring apparatus according to an embodiment of the present invention. FIG. 10 is a diagram for explaining the measurement of performance degradation information by the power line filter performance monitoring apparatus according to an embodiment of the present invention.

As illustrated in FIG. 9, the performance degradation monitoring unit 210 of the power line filter performance monitoring apparatus 200 measures currents, temperatures, and vibrations of individual components constituting the power line filter 100. Also, the performance degradation monitoring unit 210 may transmit the results of measurement of the currents, temperatures, and vibrations to the manager terminal 300 through a communication unit.

Here, the frequency characteristic measurement unit 220 of the power line filter performance monitoring apparatus 200 may measure the currents, temperatures, and vibrations of the power line filter 100 using a vibration sensor 221, a temperature sensor 223, and current sensors 225 (225-1 to 225-3), as illustrated in FIG. 10.

Further, the frequency characteristic measurement unit 220 of the power line filter performance monitoring apparatus 200 measures the frequency characteristics of the power line filter 100. The frequency characteristic measurement unit 220 may measure the frequency characteristics of the low-pass filter through online ports at the time at which a change in the performance of each component of the power line filter 100 or the low-pass filter is predicted.

Here, as illustrated in FIG. 10, the frequency characteristic measurement unit 220 may measure frequency characteristics using online measurement ports (port #1 and port #2) respectively connected to the input power line and the output power line of the power line filter 100. Further, the online measurement ports may measure the frequency characteristics of the low-pass filter in the state in which the power line filter 100 is not removed from a power supply.

The conventional technology provides only information on the states of degradation of a component for surge suppression, and cannot provide integrated information including information on the state of degradation of a component constituting a low-pass filter. Further, in the conventional technology, it is difficult to efficiently provide information for maintenance and management to the manager of facilities in which a plurality of power line filters are operated.

However, the power line filter performance monitoring apparatus 200 according to the embodiment of the present invention may diagnose the performance of the power line filter based on information on the states of degradation of components of the power line filter and integrated performance information of the power line filter. Further, the power line filter performance monitoring apparatus 200 may be utilized to construct a central management system which remotely monitors a plurality of power line filters.

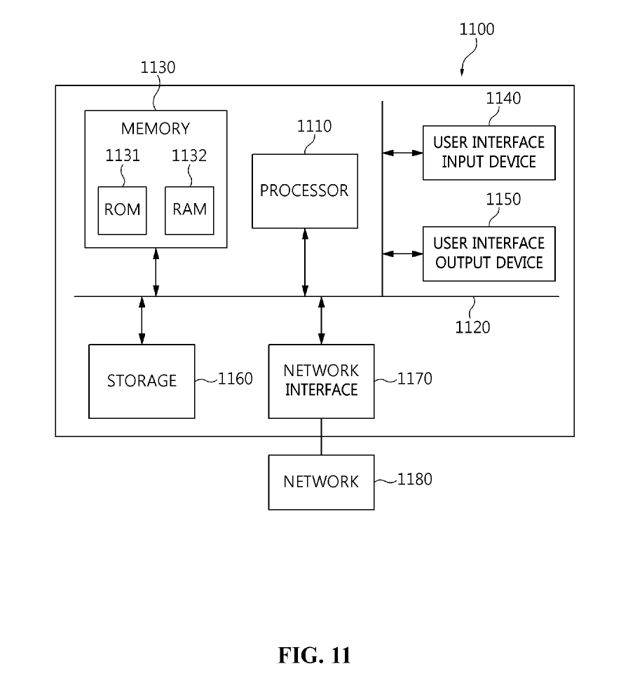

FIG. 11 is a block diagram illustrating a computer system according to an embodiment of the present invention.

Referring to FIG. 11, the embodiment of the present invention may be implemented in a computer system 1100 such as a computer-readable storage medium. As shown in FIG. 11, the computer system 1100 may include one or more processors 1110, memory 1130, a user interface input device 1140, a user interface output device 1150, and storage 1160, which communicate with each other through a bus 1120. The computer system 1100 may further include a network interface 1170 connected to a network 1180. Each processor 1110 may be a Central Processing Unit (CPU) or a semiconductor device for executing processing instructions stored in the memory 1130 or the storage 1160. Each of the memory 1130 and the storage 1160 may be any of various types of volatile or nonvolatile storage media. For example, the memory 1130 may include Read-Only Memory (ROM) 1131 or Random Access Memory (RAM) 1132.

Therefore, the embodiment of the present invention may be implemented as a non-temporary computer-readable medium in which a computer-implemented method is recorded or in which computer-executable instructions are recorded. When the computer-executable instructions are executed by the processor, the instructions may perform the method according to at least one aspect of the present invention.

In accordance with the present invention, the occurrence of a fault and the degradation of performance in a power line filter in operation may be remotely monitored.

In accordance with the present invention, the characteristics of blocking the flow of a high-power surge into a power line filter and the frequency cutoff characteristics of the power line filter may be checked during the operation of the power line filter.

In accordance with the present invention, operating performance may be checked and the basis of maintenance and repair planning may be secured and provided without stopping the operation of a power line filter.

In accordance with the present invention, the states of degradation of individual components constituting a power line filter and the integrated operating performance of the power line filter may be checked.

In accordance with the present invention, a plurality of power line filters may be efficiently maintained in an environment in which the power line filters are simultaneously monitored.

As described above, in the apparatus and method for monitoring the performance of a power line filter according to the present invention, the configurations and schemes in the above-described embodiments are not limitedly applied, and some or all of the above embodiments can be selectively combined and configured such that various modifications are possible.

What is claimed is:

1. An apparatus for monitoring performance of a power line filter, comprising:
a performance degradation monitoring unit for monitoring performance degradation of individual components constituting a power line filter, and then generating performance degradation information;
a frequency characteristic measurement unit for measuring frequency characteristics of the power line filter; and
a performance monitoring unit for determining at least one of an operating state and performance of the power line filter based on the performance degradation information of the individual components and information on the frequency characteristics of the power line filter.

2. The apparatus of claim 1, wherein the performance degradation monitoring unit generates the performance degradation information including at least one of leakage current information of the individual components, charging current information of the individual components, temperature information, and vibration information.

3. The apparatus of claim 2, wherein the performance degradation monitoring unit monitors performance degradation of the components that comprise at least one of a surge-protection device and a capacitor of the power line filter.

4. The apparatus of claim 2, further comprising a communication unit for transmitting at least one of the performance degradation information and the frequency characteristic information that are monitored at a preset period to an external manager terminal.

5. The apparatus of claim 1, wherein the frequency characteristic measurement unit measures the frequency characteristics of the power line filter in a power-connected state, using online measurement ports connected to an input stage and an output stage of the power line filter.

6. The apparatus of claim 5, wherein the frequency characteristic measurement unit measures the frequency characteristics of the power line filter using a vector network analyzer.

7. The apparatus of claim 1, wherein the performance monitoring unit determines the operating state and the performance of the power line filter using criteria information that includes at least one of performance degradation criteria information for the individual components and frequency characteristic criteria information.

8. The apparatus of claim 7, wherein the criteria information is set based on at least one of state information when the power line filter is initially installed and state information when a configuration of the power line filter is changed.

9. The apparatus of claim 8, wherein the performance monitoring unit resets at least one of a period at which the performance degradation is monitored and the criteria information in accordance with a time elapsed since installation of the power line filter and the components.

10. The apparatus of claim 7, wherein the frequency characteristic measurement unit measures frequency characteristics of the power line filter if it is determined that, as a result of monitoring the performance degradation of the individual components, the performance degradation does not satisfy the performance degradation criteria information for the individual components.

11. A method for monitoring performance of a power line filter, the method being performed by an apparatus for monitoring performance of a power line filter, the method comprising:
monitoring performance degradation of individual components constituting a power line filter, and then generating performance degradation information;
measuring frequency characteristics of the power line filter; and
determining at least one of an operating state and performance of the power line filter based on the performance degradation information of the individual components and information on the frequency characteristics of the power line filter.

12. The method of claim 11, wherein monitoring the performance degradation of the individual components is configured to generate the performance degradation information including at least one of leakage current information of the individual components, charging current information of the individual components, temperature information, and vibration information.

13. The method of claim 12, wherein monitoring the performance degradation of the individual components is configured to monitor performance degradation of the components that comprise at least one of a surge-protection device and a capacitor of the power line filter.

14. The method of claim 12, further comprising transmitting at least one of the monitored performance degradation information and the frequency characteristic information that are monitored at a preset period to an external manager terminal.

15. The method of claim 11, wherein measuring the frequency characteristics is configured to measure the frequency characteristics of the power line filter in a power-connected state using online measurement ports connected to an input stage and an output stage of the power line filter.

16. The method of claim 15, wherein measuring the frequency characteristics is configured to measure the frequency characteristics of the power line filter using a vector network analyzer.

17. The method of claim 11, wherein determining the at least one of the operating state and the performance of the power line filter is configured to determine the operating state and the performance of the power line filter using criteria information that includes at least one of performance degradation criteria information for the individual components and frequency characteristic criteria information.

18. The method of claim 17, wherein the criteria information is set based on at least one of state information when the power line filter is initially installed and state information when a configuration of the power line filter is changed.

19. The method of claim 18, further comprising resetting at least one of a period at which the performance degradation is monitored and the criteria information in accordance with a time elapsed since installation of the power line filter and the components.

20. The method of claim 17, wherein measuring the frequency characteristics is configured to measure frequency characteristics of the power line filter if it is determined that, as a result of monitoring the performance degradation of the individual components, the performance degradation does not satisfy the performance degradation criteria information for the individual components.
